(19) United States
(12) Patent Application Publication
(10) Pub. No.: US 2018/0083185 A1
(43) Pub. Date: Mar. 22, 2018

(54) MAGNETIC MEMORY DEVICE

(71) Applicant: TOSHIBA MEMORY CORPORATION, Tokyo (JP)

(72) Inventors: Tadashi KAI, Yokohama Kanagawa (JP); Kwilu AUGSTIN, Yokohama Kanagawa (JP)

(73) Assignee: TOSHIBA MEMORY CORPORATION, Tokyo (JP)

(21) Appl. No.: 15/463,304

(22) Filed: Mar. 20, 2017

Related U.S. Application Data
(60) Provisional application No. 62/396,080, filed on Sep. 16, 2016.

(51) Int. Cl. H01L 43/02; H01L 43/10; H01L 27/22; G11C 11/16; H01L 43/08

(52) U.S. Cl. CPC H01L 43/02; H01L 43/10; H01L 43/08; G11C 11/161; H01L 27/228

(57) ABSTRACT

According to one embodiment, a magnetic memory device includes a stacked structure including a first layer having a variable magnetization direction, a second layer having a fixed magnetization direction, a third layer between the first and second layers, adjacent to the first main surface of the first layer and the first main surface of the second layer, and functioning as a tunnel barrier, and a conductive fourth layer including a first main surface adjacent to the second main surface of the first layer, wherein a first resistance between the second main surface of the first layer and the second main surface of the second layer and a second resistance between the first main surface of the first layer and the second main surface of the fourth layer change based on the magnetization direction of the first layer.

### CROSS-REFERENCE TO RELATED APPLICATIONS

This application claims the benefit of U.S. Provisional Application No. 62/396,080, filed Sep. 16, 2016, the entire contents of which are incorporated herein by reference.

### FIELD

Embodiments described herein relate generally to a magnetic memory device.

### BACKGROUND

A magnetic memory device (semiconductor integrated circuit device) in which a magnetoresistive element and a MOS transistor are integrated on a semiconductor substrate is suggested.

In the above magnetic memory device, binary data is stored based or the resistive state (low or high resistive state) of the magnetoresistive element. To realize a high-performance magnetic memory device, it is important that the ratio of the resistance in a high resistive state to the resistance in a low resistive state be high. In other words, it is important to realize a high MR ratio.

However, when the magnetoresistive element is small, it is difficult to obtain a high MR ratio.

### BRIEF DESCRIPTION OF THE DRAWINGS

FIG. 1 is a cross-sectional view schematically showing a structure of a magnetic memory device according to an embodiment.

FIG. 2 schematically shows a first example of the magnetization direction and the spin direction of a magnetoresistive element shown in FIG. 1.

FIG. 3 schematically shows a second example of the magnetization direction and the spin direction of the magnetoresistive element shown in FIG. 1.

FIG. 4 schematically shows a third example of the magnetization direction and the spin direction of the magnetoresistive element shown in FIG. 1.

FIG. 5 shows the relationship between the thickness of an antiferromagnetic layer and an exchange coupling energy (exchange coupling constant) Jex.

FIG. 6 shows the relationship between the composition of the antiferromagnetic layer and an exchange coupling energy (exchange coupling constant) Jex.

FIG. 7 schematically shows a structure of a semiconductor integrated circuit device for which the magnetoresistive element of the embodiment is used.

### DETAILED DESCRIPTION

In general, according to one embodiment, a magnetic memory device includes a stacked structure including: a first layer including first and second main surfaces, and having a variable magnetization direction; a second layer including first and second main surfaces, and having a fixed magnetization direction; a third layer provided between the first layer and the second layer, adjacent to the first main surface of the first layer and the first main surface of the second layer, and functioning as a tunnel barrier; and a conductive fourth layer including first and second main surfaces, the first main surface of the fourth layer being adjacent to the second main surface of the first layer, wherein a first resistance between the second main surface of the first layer and the second main surface of the second layer and a second resistance between the first main surface of the first layer and the second main surface of the fourth layer change based on the magnetization direction of the first layer.

Embodiments will be described hereinafter with reference to the accompanying drawings.

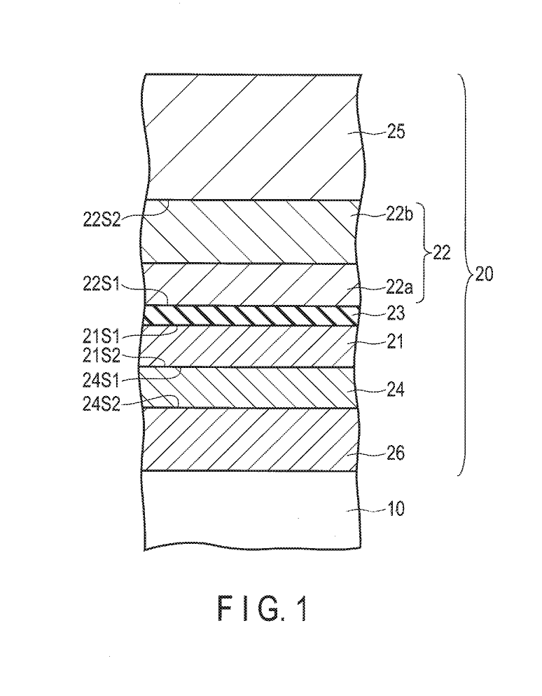

FIG. 1 is a cross-sectional view schematically showing a structure of a magnetic memory device according to an embodiment.

As shown in FIG. 1, a stacked structure 20 is provided on an underlying area 10. A magnetoresistive element is formed by the stacked structure 20. The magnetoresistive element is also called a magnetic tunnel junction (MTJ) element.

The underlying area 10 includes a semiconductor substrate, a MOS transistor, an interconnect, an interlayer insulating film, etc.

The stacked structure 20 includes a storage layer (first layer) 21, a reference layer (second layer) 22, a tunnel barrier layer (third layer) 23, an antiferromagnetic layer (fourth layer) 24, a shift canceling layer (fifth layer) 25 and an underlayer 26.

The storage layer (first layer) 21 includes a first main surface 21S1 and a second main surface 21S2, and has a variable magnetization direction. The storage layer 21 is formed of a ferromagnetic material, and contains at least iron (Fe) and cobalt (Co). In addition to iron (Fe) and cobalt (Co), the storage layer 21 may contain boron (B). In the present embodiment, the storage layer 21 is formed of cobalt iron boron (CoFeB). An Fe-based alloy, a Co-based alloy, an Ni-based alloy or an Mn-based alloy may be used for the storage layer 21.

The reference layer (second layer 22) includes a first main surface 22S1 and a second main surface 22S2, and has a fixed magnetization direction. The reference layer 22 includes a first sub-magnetic layer portion 22a and a second sub-magnetic layer portion 22b. The first sub-magnetic layer portion 22a is formed of a ferromagnetic material, and contains at least iron (Fe) and cobalt (Co). In addition to iron (Fe) and cobalt (Co), the first sub-magnetic layer portion 22a may contain boron (B). In the present embodiment, the first sub-magnetic layer portion 22a is formed of cobalt iron boron (CoFeB). An Fe-based alloy, a Co-based alloy, an Ni-based alloy or an Mn-based alloy may be used for the first sub-magnetic layer portion 22a. The second sub-magnetic layer portion 22b is formed of a ferromagnetic material, and contains at least one of cobalt (Co) and iron (Fe), and at least one element selected from platinum (Pt), nickel (Ni) and palladium (Pd). An alloy containing a rare earth element such as Tb or Gd may be used for the second sub-magnetic layer portion 22b. In the present embodiment, the second sub-magnetic layer portion 22b is formed of cobalt platinum (CoPt).

The tunnel barrier layer (third layer) 23 is provided between the storage layer 21 and the reference layer 22. The tunnel harrier layer 23 is adjacent to (and in contact with) the first main surface 21S1 of the storage layer 21 and the first main surface 22S1 of the reference layer 22, and functions as a tunnel barrier. The tunnel barrier layer 23 is formed of an insulating material, for example, an oxide insulating material. In the present embodiment, the tunnel barrier layer 23 is formed of magnesium oxide (MgO).

The antiferromagnetic layer (fourth layer) 24 includes a first main surface 24S1 and a second main surface 24S2. The first main surface 24S1 of the antiferromagnetic layer 24 is adjacent to (and in contact with) the second main surface 21S2 of the storage layer 21. The antiferromagnetic layer 24 is conductive. The antiferromagnetic layer 24 is formed of an antiferromagnetic material such as an Mn-based alloy (iridium manganese [IrMn], platinum manganese [PtMn], nickel manganese [NiMn], iron manganese [FeMn], etc.), an oxide of a ferromagnetic element (nickel oxide [NiO], cobalt oxide [CoO], etc.) , or a rare-earth-metal-based alloy (terbium cobalt iron [TbCoFe], etc). A ferrimagnetic layer formed of a ferrimagnetic material may be used for the fourth layer 24.

The shift canceling layer (fifth layer) 25 is adjacent to (and in contact with) the second main surface 22S2 of the reference layer 22, and has a fixed magnetization direction antiparallel to the magnetization direction of the reference layer 22. The shift canceling layer 25 is formed of a ferromagnetic material. The shift canceling layer 25 contains at least one of cobalt (Co) and iron (Fe), and at least one element selected from platinum (Pt), nickel (Ni) and palladium (Pd). An alloy containing a rare earth element such as Tb or Gd may be used for the shift cancelling layer 25. In the present embodiment, the shift cancelling layer 25 is formed of cobalt platinum (CoPt). The magnetic field applied from the reference layer 22 to the storage layer 21 can be canceled by providing the shift canceling layer 25. Normally, an interlayer portion (not shown) formed of ruthenium (Ru), etc., is provided between the shift canceling layer 25 and the reference layer 22. A top electrode (not shown) is connected to the shift canceling layer 25.

The underlayer 26 is provided between the underlying area 10 and the antiferromagnetic layer 24. A bottom electrode (not shown) is connected to the underlayer 26.

In the magnetoresistive element comprising the stacked structure 20, a first resistance R1 between the second main surface 21S2 of the storage layer 21 and the second main surface 22S2 and the reference layer 22 changes based on the magnetization direction of the storage layer 21. A second resistance R2 between the first main surface 21S1 of the storage layer 21 and the second main surface 24S2 of the antiferromagnetic layer 24 also changes based on the magnetization direction of the storage layer 21. Specifically, the storage layer 21 is selectively in a first state where the magnetization direction is parallel to the magnetization direction of the reference layer 22, and a second state where the magnetization direction is antiparallel to the magnetization direction of the reference layer 22. Both the first resistance R1 and the second resistance R2 are low when the storage layer 21 is in the first state in comparison with when the storage layer 21 is in the second state.

In the present embodiment, the magnetoresistive element comprises the above structure. Thus, even when the element is small, a high MR ratio can be realized. Additional explanations are provided below.

In general, the resistance of a magnetoresistive element (in particular, resistance corresponding to the above first resistance R1) depends on the resistance based on the tunnel magnetoresistive effect generated by a storage layer, a reference layer and a tunnel barrier layer. Specifically, the resistance of the magnetoresistive element is low when the magnetization direction of the storage layer is parallel to the magnetization direction of the reference layer in comparison with when the magnetization direction of the storage layer is antiparallel to the magnetization direction of the reference layer. When the magnetization direction of the storage layer is parallel to that of the reference layer, the magnetoresistive element (stacked structure) is in a low resistive state. When the magnetization direction of the storage layer is antiparallel to that of the reference layer, the magnetoresistive element (stacked structure) is in a high resistive state. Thus, the magnetoresistive element is allowed to store binary data (0 or 1) in accordance with the resistive state (low or high resistive state). The resistive state (low or high resistive state) of the magnetoresistive element can be set in accordance with the direction of write current flowing in the magnetoresistive element (stacked structure).

However, when the magnetoresistive element is small, the ratio of the resistance in a high resistive state to the resistance in a low resistive state is difficult to be high. Thus, it is difficult to obtain a magnetoresistive element having a high MR ratio. In general, when the magnetoresistive element is small, the areal resistance of the magnetoresistive element should be reduced. To reduce the areal resistance, the thickness of the tunnel barrier layer needs to be reduced. However, when the thickness of the tunnel barrier layer is reduced, the MR ratio is decreased. Thus, when the magnetoresistive element is small, the MR ratio is difficult to be high.

In the present embodiment, the magnetoresistive element comprises the antiferromagnetic layer 24 adjacent to the storage layer 21 which is a ferromagnetic layer. Thus, the antiferromagnetic layer 24 is in contact with the storage layer 21 which is a ferromagnetic layer. The second resistance R2 depends on the resistance based on the magnetoresistive effect applied between the storage layer 21 and the antiferromagnetic layer 24. Since the spin direction of the antiferromagnetic layer 24 changes based on the magnetization direction of the storage layer 21, the resistance between the storage layer 21 and the antiferromagnetic layer 24 changes based on the magnetization direction of the storage layer 21. Thus, the second resistance R2 (the resistance based on an anisotropy magnetoresistive effect) when the first resistance R1 (the resistance based on a tunnel magnetoresistive effect) is in a low resistive state can be made lower than the second resistance R2 when the first resistance R1 is in a high resistive state by appropriately setting the relationship between the spin direction of the antiferromagnetic layer 24 and the magnetization direction of the storage layer 21. As a result, the ratio of the value of R1+R2 when the first resistance R1 is in a high resistive state to the value of R1+R2 when the first resistance R1 is in a low resistive state can be made high. In this way, even when the magnetoresistive element is small, the MR ratio can be high.

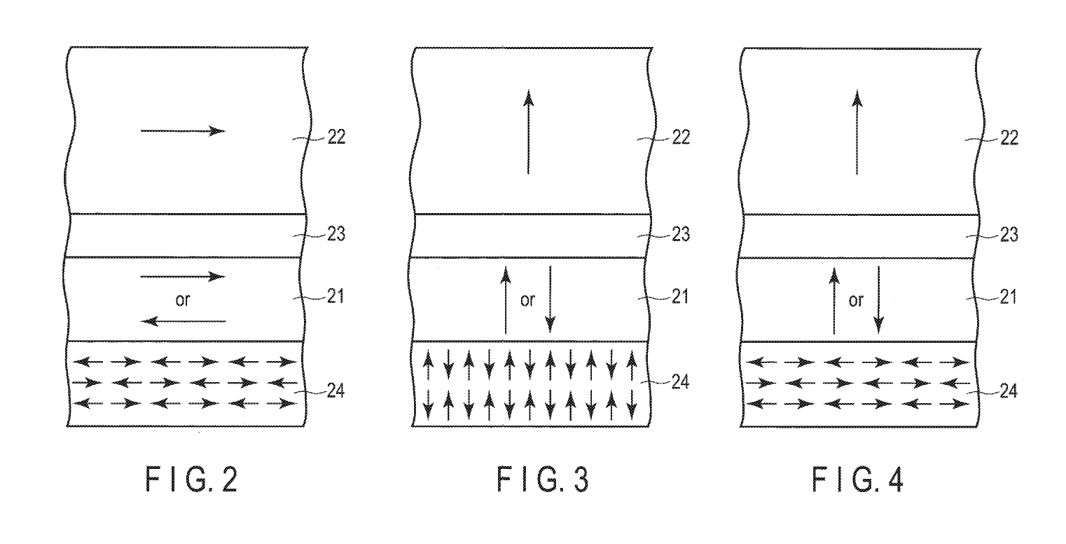

FIG. 2 schematically shows a first example of the magnetization direction and the spin direction of the magnetoresistive element shown in FIG. 1. In the first example, the storage layer 21 and the reference layer 22 have in-plane magnetization. The magnetization direction of the storage layer 21 is parallel to the main surfaces of the storage layer 21. The magnetization direction of the reference layer 22 is parallel to the main surfaces of the reference layer 22. The spin directions of the antiferromagnetic layer 24 are parallel to the main surfaces of the antiferromagnetic layer 24.

FIG. 3 schematically shows a second example of the magnetization direction and the spin direction of the magnetoresistive element shown in FIG. 1. In the second example, the storage layer 21 and the reference layer 22 have perpendicular magnetization. The magnetization direction of the storage layer 21 is perpendicular to the main surfaces of the storage layer 21. The magnetization direction of the reference layer 22 is perpendicular to the main surfaces of the reference layer 22. The spin directions of the antiferromagnetic layer 24 are perpendicular to the main surfaces of the antiferromagnetic layer 24.

In the first and second examples, when the magnetization direction of the storage layer 21 is parallel to that of the reference layer 22, in other words, when the first resistance R1 is in a low resistive state, one of the spin directions of the antiferromagnetic layer 24 is parallel to the magnetization direction of the storage layer 21, and the other spin direction of the antiferromagnetic layer 24 is antiparallel to the magnetization direction of the storage layer 21. In this case, the second resistance R2 is also in a low resistive state, and further, the magnetoresistive element is in a low resistive state as a whole. When the magnetization direction of the storage layer 21 is antiparallel to that of the reference layer 22, in other words, when the first resistance R1 is in a high resistive state, one of the spin directions of the antiferromagnetic layer 24 deviates from the state parallel to the magnetization direction of the storage layer 21, and the other spin direction of the antiferromagnetic layer 24 deviates from the state antiparallel to the magnetization direction of the storage layer 21. As a result, the second resistance R2 is also in a high resistive state, and further, the magnetoresistive element is in a high resistive state as a whole.

FIG. 4 schematically shows a third example of the magnetization direction and the spin direction of the magnetoresistive element shown in FIG. 1. In the third example, the storage layer 21 and the reference layer 22 have perpendicular magnetization. The magnetization direction of the storage layer 21 is perpendicular to the main surfaces of the storage layer 21. The magnetization direction of the reference layer 22 is perpendicular to the main surfaces of the reference layer 22. The spin directions of the antiferromagnetic layer 24 are parallel to the main surfaces of the antiferromagnetic layer 24.

In the third example, when the magnetization direction of the storage layer 21 is parallel to that of the reference layer 22, in other words, when the first resistance R1 is in a low resistive state, both of the spin directions of the antiferromagnetic layer 24 are set to appropriate predetermined directions such that the second resistance R2 is in a low resistive state. Thus, the magnetoresistive element is also in a low resistive state as a whole. When the magnetization direction of the storage layer 21 is antiparallel to that of the reference layer 22, in other words, when the first resistance R1 is in a high resistive state, both of the spin directions of the antiferromagnetic layer 24 deviate from the above appropriate predetermined directions. As a result, the second resistance R2 is also in a high resistive state, and further, the magnetoresistive element is in a high resistive state as a whole.

As is clear from the above description, in all of the first to third examples, the ratio of the value of R1+R2 when the first resistance R1 is in a high resistive state to the value of R1+R2 when the first resistance R1 is in a low resistive state can be made high. Thus, it is possible to obtain a magnetoresistive element having an MR ratio higher than a common MR ratio based on a tunnel effect.

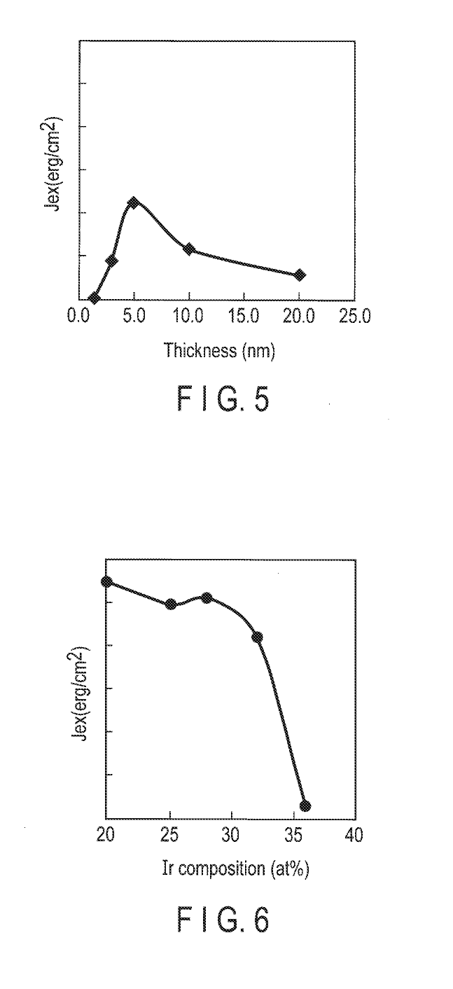

FIG. 5 shows the relationship between the thickness of the antiferromagnetic layer and an exchange coupling energy (exchange coupling constant) Jex. As the material of the antiferromagnetic layer, IrMn (Ir: 20%, Mn: 80%) is used. As is clear from FIG. 5, when the thickness of the IrMn layer is approximately 3 to 10 nm, the Jex is great. When the thickness of the IrMn layer is approximately 5 nm, the Jex is the greatest. When the IrMn layer is used for the antiferromagnetic layer, the MR ratio of the magnetoresistive element can be made high by forming the IrMn layer so as to be thin, specifically, so as to have a thickness of approximately 3 to 10 nm.

FIG. 6 shows the relationship between the composition of the antiferromagnetic layer and an exchange coupling energy (exchange coupling constant) Jex. As the material of the antiferromagnetic layer, IrMn is used. The lateral axis represents the Ir composition in the IrMn layer. As is clear from FIG. 6, when the Ir composition is less than or equal to approximately 30 at %, the Jex is great. When the IrMn layer is used for the antiferromagnetic layer, the MR ratio of the magnetoresistive element can be made high by setting the Ir composition to approximately 30 at % or less.

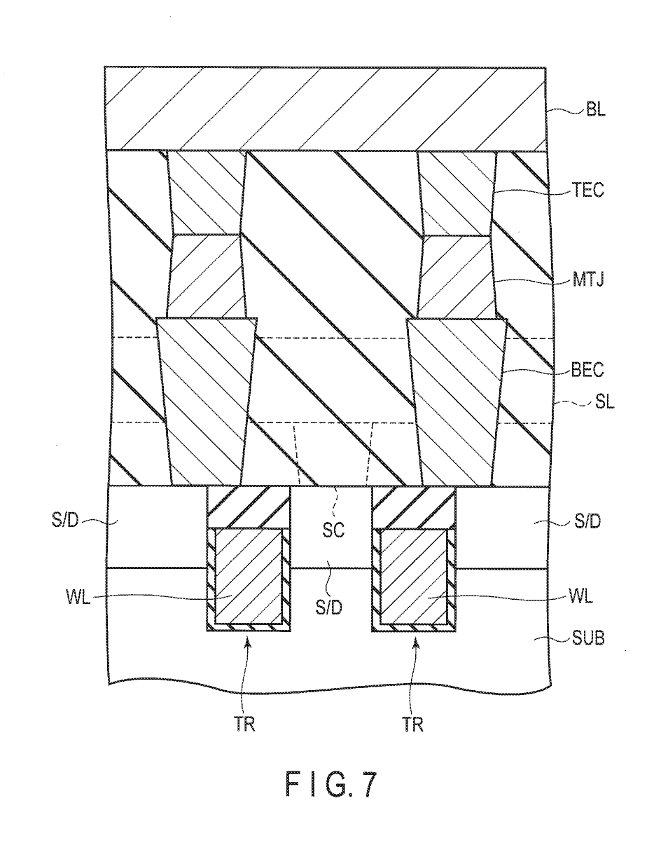

FIG. 7 schematically shows a structure of a semiconductor integrated circuit device for which the magnetoresistive element (MTJ element) of the present embodiment is used.

A buried gate MOS transistor TR is formed inside a semiconductor substrate SUB. The gate electrode of the MOS transistor TR is used as a word line WL. A bottom electrode BEC is connected to one of the source/drain areas S/D of the MOS transistor TR. A source line contact SC is connected to the other source/drain area S/D.

A magnetoresistive element MTJ is formed on the bottom electrode BEC. A top electrode TEC is formed on the magnetoresistive element MTJ. A bit line BL is connected to the top electrode TEC. A source line SL is connected to the source line contact SC.

When the magnetoresistive element of the present embodiment is applied to the semiconductor integrated circuit device shown in FIG. 7, the semiconductor integrated circuit device (magnetic memory device) can exhibit excellent performance.

In the above embodiment, the antiferromagnetic layer 24, the storage layer 21, the tunnel barrier layer 23, the reference layer 22 and the shift canceling layer 25 are stacked from the bottom layer side to the top layer side. However, the stacked order may be reversed.

In the above embodiment, an antiferromagnetic layer is used for the fourth layer 24. However, in general, it is possible to use, for the fourth layer 24, a material layer in which the second resistance R2 between the first main surface 21S1 of the first layer (storage layer) 21 and the second main surface 24S2 of the fourth layer 24 changes based on the magnetization direction of the first layer (storage layer) 21. In particular, for the fourth layer 24, it is possible to use a material layer in which the second resistance R2 is low when the first layer (storage layer) 21 is in the first state (in other words, when the magnetization direction of the first layer [storage layer] 21 is parallel to that of the second layer [reference layer] 22) in comparison with when the first layer (storage layer) 21 is in the second state (in other words, when the magnetization direction of the first layer [storage layer] 21 is antiparallel to that of the second layer [reference layer] 22).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory device comprising a stacked structure including:
a first layer including first and second main surfaces, and having a variable magnetization direction;
a second layer including first and second main surfaces, and having a fixed magnetization direction;
a third layer provided between the first layer and the second layer, adjacent to the first main surface of the first layer and the first main surface of the second layer, and functioning as a tunnel barrier; and
a conductive fourth layer including first and second main surfaces, the first main surface of the fourth layer being adjacent to the second main surface of the first layer, wherein
a first resistance between the second main surface of the first layer and the second main surface of the second layer and a second resistance between the first main surface of the first layer and the second main surface of the fourth layer change based on the magnetization direction of the first layer.

2. The magnetic memory device of claim 1, wherein
the first layer is selectively in a first state where the magnetization direction is parallel to the magnetization direction of the second layer, and in a second state where the magnetization direction is antiparallel to the magnetization direction of the second layer.

3. The magnetic memory device of claim 2, wherein
both the first resistance and the second resistance are low when the first layer is in the first state in comparison with when the first layer is in the second state.

4. The magnetic memory device of claim 1, wherein
the magnetization direction of the first layer is parallel to the main surfaces of the first layer, and
the magnetization direction of the second layer is parallel to the main surfaces of the second layer.

5. The magnetic memory device of claim 1, wherein
the magnetization direction of the first layer is perpendicular to the main surfaces of the first layer, and
the magnetization direction of the second layer is perpendicular to the main surfaces of the second layer.

6. The magnetic memory device of claim 1, wherein
the first resistance depends on resistance based on a tunnel magnetoresistive effect generated by the first layer, the second layer and the third layer.

7. The magnetic memory device of claim 1, wherein
the fourth layer has antiferromagnetism or ferrimagnetism.

8. The magnetic memory device of claim 7, wherein
a spin direction of the fourth layer changes based on the magnetization direction of the first layer.

9. The magnetic memory device of claim 7, wherein
the magnetization direction of the first layer is parallel to the main surfaces of the first layer,
the magnetization direction of the second layer is parallel to the main surfaces of the second layer, and
a spin direction of the fourth layer is parallel to the main surfaces of the fourth layer.

10. The magnetic memory device of claim 7, wherein
the magnetization direction of the first layer is perpendicular to the main surfaces of the first layer,
the magnetization direction of the second layer is perpendicular to the main surfaces of the second layer, and
a spin direction of the fourth layer is perpendicular to the main surfaces of the fourth layer.

11. The magnetic memory device of claim 7, wherein
the magnetization direction of the first layer is perpendicular to the main surfaces of the first layer,
the magnetization direction of the second layer is perpendicular to the main surfaces of the second layer, and
a spin direction of the fourth layer is parallel to the main surfaces of the fourth layer.

12. The magnetic memory device of claim 7, wherein
the second resistance depends on resistance based on a magnetoresistive effect applied between the first layer and the fourth layer.

13. The magnetic memory device of claim 7, wherein
the fourth layer is formed of an Mn-based alloy, an oxide of a ferromagnetic element, a rare-earth-metal-based alloy or a ferrimagnetic material.

14. The magnetic memory device of claim 1, wherein
the first layer contains iron (Fe) and cobalt (Co).

15. The magnetic memory device of claim 14, wherein
the first layer further contains boron (B).

16. The magnetic memory device of claim 1, wherein
the second layer includes a first sub-magnetic layer portion containing iron (Fe) and cobalt (Co).

17. The magnetic memory device of claim 16, wherein
the first sub-magnetic layer portion further contains boron (B).

18. The magnetic memory device of claim 16, wherein
the second layer further includes a second sub-magnetic layer portion containing at least one of cobalt (Co) and iron (Fe), and at least one element selected from platinum (Pt), nickel (Ni) and palladium (Pd).

19. The magnetic memory device of claim 1, wherein
the third layer is formed of an oxide insulating material.

20. The magnetic memory device of claim 1, wherein
the stacked structure further includes a fifth layer adjacent to the second main surface of the second layer and having a fixed magnetization direction antiparallel to the magnetization direction of the second layer.
